(19) United States
(12) Patent Application Publication
(10) Pub. No.: US 2006/0163725 A1
(43) Pub. Date: Jul. 27, 2006

(54) Wiring board and production method thereof

(76) Inventors: Toshio Haba, Tokai (JP); Hiroshi Yoshida, Mito (JP); Haruo Akahoshi, Hitachi (JP); Hitoshi Suzuki, Hitachi (JP); Akira Chinda, Hitachi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/205,175

(22) Filed: Aug. 17, 2005

(30) Foreign Application Priority Data
Jan. 27, 2005 (JP) 2005-019437

(51) Int. Cl. H01L 23/48; H01L 21/44

(52) U.S. Cl. 257/737; 438/687; 438/674; 438/614; 257/762

(57) ABSTRACT

It is an object of the present invention to provide a wiring board having high-density wiring with a controlled shape without masking by a resist film and a production method thereof. In the present invention, the production method of a wiring board having copper wiring on an insulating substrate includes the steps of forming a metal seed layer on the insulating substrate, the metal seed layer having a roughened shape in a portion on which the copper wiring or a bump is to be formed, and forming an electroplated film of copper or an alloy of copper through electroplating on the portion of the metal seed layer having the roughened shape. A substance for suppressing the plating reaction is added to a plating bath to provide an angle of 90 degrees or smaller between a surface of the insulating substrate and a side of the electroplated film.

### INCORPORATION BY REFERENCE

The present application claims priority from Japanese application JP2005-019437 filed on Jan. 27, 2005, the content of which is hereby incorporated by reference into this application.

### BACKGROUND OF THE INVENTION

The present invention relates to a wiring board having a wiring made of copper or an alloy of copper, and to a production method thereof.

Electronic devices with smaller size, lighter weight, and lower cost are needed increasingly year after year. This requires wiring boards used in those electronic devices to have high-density wiring formed with low cost in order to achieve smaller size and lighter weight. Production methods of wiring boards can be broadly classified into two: a subtractive method and an additive method. In the subtractive method, an etching resist is formed on a copper foil applied to a substrate and the copper is etched away except the portions which will serve as wiring, thereby forming wiring. In the additive method, a resin substrate is covered with a plating resist film except the portions which will serve as wiring and a plated film is formed only in the portions which will serve as wiring.

In the conventional production methods of wiring boards, both of the subtractive method and additive methods require the masking of the substrate surface by the resist. The masking by the resist film needs the steps of film formation, exposure, and development. These steps involve high cost due to the use of chemicals and the treatment of waste liquid. In addition, the large number of the steps cause a long processing time. Thus, the process of masking by the resist film has been a bottleneck in producing wiring boards with low cost in a short time.

As a solution therefor, production methods of wiring boards have been studied which use no masking by a resist. One of them is a known method in which a metal seeding solution layer is formed on a substrate surface and exposed to light at an appropriate wavelength to form a metal seed layer and then plating or the like is performed to form a metal film (for example, JP-A-7-336018). In another known method, a plate is used to form a chemically changed pattern on a substrate surface and electroless plating is performed to form wiring (for example, JP-A-2002-184752).

The conventional methods for forming a wiring board without masking by a resist have the following problem. For example, the method in which a metal seeding solution layer is formed on a substrate surface and exposed to light to form a metal seed layer and then plating or the like is performed to form a metal film has difficulty in forming wiring with higher density since the shape of the plated film serving as wiring is not sufficiently considered. The reason thereof is as follows. When plating is performed without using a resist film, the plated film is isotropically grown from the seed layer. The isotropically grown plated film creates a semicircular cross-section in the plated wiring to occupy a larger area on the wiring board as compared with rectangular wiring having the same sectional area. Therefore, the wiring with the semicircular cross-section is disadvantageous in providing higher density as compared with the rectangular wiring.

In the method in which a plate is used to form a chemically changed pattern on a substrate surface and electroless plating is performed to form wiring, the shape of the plated film serving as the wiring is not considered sufficiently. When plating is performed without using a resist, the plated film has a larger width than the seed layer, which is disadvantageous in achieving higher density in wiring. In addition, the wiring cannot be formed with a width as designed in the underlying film.

Thus, it is an object of the present invention to provide a wiring board having high-density wiring with a controlled shape without masking by a resist and a production method thereof.

### SUMMARY OF THE INVENTION

According to the present invention, a method of producing wiring board includes the steps of forming a metal seed layer on an insulating substrate, the metal seed layer having a roughened area on which copper wiring or a bump is to be formed, and forming an electroplated film of copper or an alloy of copper through electroplating on the roughened area of the metal seed layer. A substance for suppressing plating reaction is added to a plating bath to provide an angle of 90 degrees or smaller between a surface of the insulating substrate and a side of the electroplated film.

According to the present invention, a wiring board includes a metal seed layer on an insulating substrate, the metal seed layer having a roughened area thereon, and wiring or a bump made of copper or an alloy of copper formed through electroplating on the portion of the metal seed layer having the roughened area. An angle between a surface of the insulating substance and a side of the wiring or bump is 90 degrees or smaller.

The present invention allows high-density wiring with a controlled shape to be formed without using a resist. The angle between the wiring side and the substrate surface set to 90 degrees or smaller enables the formation of the wiring through electroplating without reducing the dimensional accuracy of the wiring.

Other objects, features and advantages of the invention will become apparent from the following description of the embodiments of the invention taken in conjunction with the accompanying drawings.

### BRIEF DESCRIPTION OF THE DRAWINGS

FIGS. 1(a), 1(b) and 1(c) are sectional views showing an example of a production method of a wiring board according to the present invention.

FIGS. 2(a), 2(b) and 2(c) are sectional views showing another example of the production method of a wiring board according to the present invention.

FIGS. 3(a), 3(b), 3(c) and 3(d) are sectional views showing yet another example of the production method of a wiring board according to the present invention.

FIGS. 4(a), 4(b), 4(c) and 4(d) are sectional views showing still another example of the production method of a wiring board according to the present invention.

FIGS. 5(a), 5(b), 5(c) and 5(d) are sectional views showing a further example of the production method of a wiring board according to the present invention.

FIGS. 6(a), 6(b), 6(c), 6(d) and 6(e) are sectional views showing a still further example of the production method of a wiring board according to the present invention.

FIGS. 7(a), 7(b), 7(c), 7(d), 7(e) and 7(f) are sectional views showing a yet further example of the production method of a wiring board according to the present invention.

FIGS. 8(a), 8(b), 8(c) and 8(d) are sectional views showing another example of the production method of a wiring board according to the present invention.

FIG. 9 shows an evaluation method of the sectional shape of wiring.

FIGS. 10(a), 10(b) and 10(c) are sectional views showing the sectional shapes of wiring provided in Examples of the present invention.

FIG. 11 is a plan view showing a wiring board viewed from an electroplated copper film.

### DETAILED DESCRIPTION OF THE INVENTION

The present inventors have found that an appropriate roughened area is formed on a metal seed layer for electroplating and plating conditions are optimized to allow the controlled deposition shape of the plated film in the portion having the roughened area. An effective approach to control of the deposition conditions of the plated film is to add a compound, as an additive, which suppresses the plating reaction and loses the plating reaction suppressing effect as the plating reaction proceeds. The property of suppressing the plating reaction can be seen from the fact that the addition of the additive increases the metal deposition overpotential. The property of losing the plating reaction suppressing effect as the plating reaction proceeds can be seen from the fact that the metal deposition rate is decreased with a higher flow rate of a plating bath, that is, with quicker supply of the additive to the metal surface. When the additive loses the plating reaction suppressing effect, the additive may be decomposed into different substrates, or reduced to a substrate with a different oxidation number.

When plating is performed with the plating bath containing such an additive, the additive loses its effect on the surface of the metal seed layer as the plating reaction proceeds, so that the effective concentration of the additive contributing to the plating reaction decreases. The portion of the metal seed layer of the roughened shape has a relatively larger surface area to consume the additive at a higher rate as compared with the portion without any roughened shape, which results in an even lower concentration of the additive near the surface of the metal seed layer of the roughened area. Thus, in the portion of the roughened shape on the metal seed layer, the additive effect of suppressing the plating reaction is reduced to increase the plating rate. Since the plating rate depends on the concentration of the additive on the surface of the metal seed layer, the shape of the plated film changes with the distribution of the additive concentration.

Since the distribution of the additive concentration can be changed by controlling the plating conditions, the shape of the plated film can also be changed by controlling the plating conditions. The distribution of the additive concentration is provided on the basis of the balance between the diffusion of the additive over the metal seed layer and the reaction rate thereof on the surface of the metal seed layer. Thus, controlling either the diffusion of the additive over the metal seed layer or the reaction rate thereof on the surface of the metal seed layer enables control of the shape of the plated film in the portion of the roughened shape.

The diffusion rate of the additive over the metal seed layer is largely affected by the concentration of the additive in the plating bath, and the reaction rate of the additive on the metal seed layer is largely affected by the current density during plating. Thus, changing the additive concentration in the plating bath or the current density during the plating can control the distribution of the additive concentration, thereby making it possible to achieve preferential deposition of the plated film on the roughened area and control of the shape of the plated film.

Description will hereinafter be made for aspects of a production method of a wiring board of the present invention.

According to one aspect, the production method includes the steps of forming the metal seed layer on the insulating substrate, forming the rough area on the metal seed layer including the portion on which wiring or a bump is to be formed, forming the electroplated film made of copper or an alloy of copper on the rough area of the metal seed layer through the electroplating, and removing the seed metal layer and the electroplated copper film except their portions having the rough area thereon. The substance for suppressing the plating reaction is added to the plating bath to provide an angle of 90 degrees or smaller between the surface of the insulating substrate and the side of the electroplated film.

According to another aspect, the production method includes the steps of forming the metal seed layer having the rough area formed thereon on the insulating substrate, planarizing the roughened shape on the metal seed layer except its portion on which the copper wiring or bumps are to be formed, forming the electroplated film made of copper or an alloy of copper through the electroplating on the metal seed layer, and removing the metal seed layer and the electroplated film except their portions having the roughened area thereon. The substance for suppressing the plating reaction is added to the plating bath to provide an angle of 90 degrees or smaller between the surface of the insulating substrate and the side of the electroplated film.

According to yet another aspect, the production method includes the steps of forming the metal seed layer serving as a power supply layer for the electroplating, forming an insulating film serving as the insulating substrate on the metal seed layer with a casting method, forming the rough area in a portion of the metal seed layer on which wiring or a bump is to be formed, forming the electroplated film made of copper or an alloy of copper through the electroplating on the portion of the metal seed layer having the rough area, and removing the metal seed layer and the electroplated film except their portions having the rough area thereon. The substance for suppressing the plating reaction is added to the plating bath to provide an angle of 90 degrees or smaller between the surface of the insulating substrate and the side of the electroplated film.

In the present invention, an arithmetic average roughness Ra (defined in JIS B0601) of the portion having the rough area of the substrate or the metal seed layer is set to be larger than Ra in the remaining portion. Alternatively, an average length of a roughness curve element RSm (defined in JIS B0601) of the portion having the rough area of the substrate or the metal seed layer is set to be smaller than RSm in the remaining portion.

It is desirable that the surface roughness of the portion having the rough area of the metal seed layer on which the plated film is preferentially formed has an arithmetic average roughness Ra (defined in JIS B0601) of 0.01 to 4 μm and has an average length of a roughness curve element RSm of 0.005 to 8 μm. More specifically, it is desirable that the surface roughness of the portion having the roughened shape of the metal seed layer has an arithmetic average roughness Ra (defined in JIS B0601) of 0.1 to 1 μm and has an average length of a roughness curve element RSm of 0.05 to 2 μm.

The substance added to the plating bath desirably increases the deposition overpotential of the metal deposition through the plating when the flow rate of the plating bath to which the substrate is added increases. As an example of such a substrate, at least one of cyanine dyes is desirably added. A particularly desirable cyanine dye is a compound shown in the formula below (X represents an anion and n represents one of the numbers 0, 1, 2, and 3).

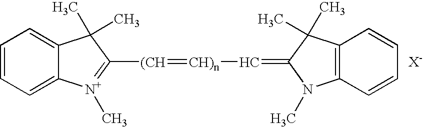

The cyanine dye desirably has a concentration of 3 to 15 mg/dm³. In the present invention, at least one substance selected from a polyether, an organic sulfur compound, and a halide ion can be added to an electrolytic copper plating bath.

The electrolytic copper plating in forming the copper film is desirably performed with a constant current at a current density of 0.1 to 2.0 A/dm².

Next, description will be made for aspects of the wiring board of the present invention.

According to one aspect, the wiring board has the metal seed layer on the insulating substrate, the metal seed layer having the rough area thereon, and wiring or bumps formed through electroplating on the portion of the metal seed layer having the rough area. An angle between a surface of the insulating substance and a side of the wiring or bump is 90 degrees or smaller. An arithmetic average roughness Ra, defined in JIS B0601, of the portion having the rough area of the substrate or the metal seed layer is larger than an arithmetic average roughness Ra of the remaining portion.

According to one aspect, the wiring board has the metal seed layer on the insulating substrate, the metal seed layer having the rough area thereon, and wiring or bumps of copper or an alloy of copper formed through electroplating on the portion of the metal seed layer having the rough area. An angle between a surface of the insulating substance and a side of the wiring or bump is 90 degrees or smaller. An average length of a roughness curve element RSm, defined in JIS B0601, of the portion having the rough area of the substrate or the metal seed layer is smaller than an average length RSm of the remaining portion.

It is desirable that the surface roughness of the portion having the rough area of the metal seed layer has an arithmetic average roughness Ra (defined in JIS B0601) of 0.01 to 4 μm, or an average length of a roughness curve element RSm of 0.005 to 8 μm. More specifically, Ra desirably has a value of 0.1 to 1 μm and RSm desirably has a value of 0.05 to 2 μm. It is most desirable that both of them fall within the abovementioned ranges.

The angle between the surface of the insulating substrate and the side of the wiring or bump is desirably equal to or larger than one degree.

In the wiring board, the plated copper or an alloy of copper desirably has a surface in parallel with the surface of the insulating substrate.

### DESCRIPTION OF PREFERRED EMBODIMENTS

Examples of the present invention will hereinafter be described. First, table 1 shows the results of Examples 1 to 22 and Comparative Example 1.

TABLE 1

| | | Additive | | | | |
|---|---|---|---|---|---|---|
| | | Concen- | Current | | | |
| | Additive | tration | Density | | | θ |
| No. | Type | [mg/dm³] | [A/dm⁻²] | Ra | RSm | [degree] |
| Example 1 | A-2 | 7.0 | 1.25 | 0.01 | 0.02 | 83 |
| Example 2 | A-2 | 7.0 | 1.25 | 0.05 | 0.04 | 83 |
| Example 3 | A-2 | 7.0 | 1.25 | 0.4 | 1.1 | 85 |
| Example 4 | A-2 | 7.0 | 1.25 | 1.5 | 1.4 | 80 |
| Example 5 | A-2 | 7.0 | 1.25 | 2.0 | 4.0 | 86 |
| Example 6 | A-2 | 7.0 | 1.25 | 0.5 | 0.6 | 83 |
| Example 7 | A-2 | 7.0 | 1.25 | 1.0 | 1.1 | 89 |
| Example 8 | A-2 | 7.0 | 1.25 | 0.4 | 3.1 | 85 |
| Example 9 | A-2 | 2.5 | 1.0 | 0.4 | 1.1 | 86 |
| Example 10 | A-2 | 5.0 | 1.0 | 0.4 | 1.1 | 85 |
| Example 11 | A-2 | 7.5 | 1.0 | 0.4 | 1.1 | 32 |
| Example 12 | A-2 | 10 | 1.0 | 0.4 | 1.1 | 19 |
| Example 13 | A-2 | 7.0 | 0.50 | 0.4 | 1.1 | 10 |
| Example 14 | A-2 | 7.0 | 1.5 | 0.4 | 1.1 | 89 |
| Example 15 | A-2 | 10 | 1.25 | 0.4 | 1.1 | 28 |
| Example 16 | A-2 | 10 | 1.37 | 0.4 | 1.1 | 45 |
| Example 17 | A-2 | 10 | 1.50 | 0.4 | 1.1 | 52 |
| Example 18 | A-1 | 7.0 | 1.25 | 0.4 | 1.1 | 80 |
| Example 19 | A-3 | 4.0 | 1.25 | 0.4 | 1.1 | 83 |
| Example 20 | A-4 | 5.0 | 1.0 | 0.4 | 1.1 | 79 |
| Example 21 | A-1 | 7.0 | 1.5 | 0.4 | 1.1 | 68 |
| | A-2 | 5.0 | | | | |
| Example 22 | A-2 | 7.0 | 1.0 | 0.4 | 1.1 | 34 |
| | B-1 | 100 | | | | |
| | C-1 | 2 | | | | |
| Comparative | A-2 | 7.0 | 1.25 | 0.007 | 10 | 135 |
| Example 1 | | | | | | |

Various symbols in the columns “Additive Type” in Table 1 represent the following chemical substances.
A-1: 2-[(1,3-Dihydro-1,3,3-trimethyl-2H-indol-2-ylidene)-methyl]-1,3,3-trimethyl-3H-indolium perchlorate
A-2: 2-[3-(1,3-Dihydro-1,3,3-trimethyl-2H-indol-2-ylidene)-1-propenyl]-1,3,3-trimethyl-3H-indolium chloride
A-3: 2-[5-(1,3-Dihydro-1,3,3-trimethyl-2H-indol-2-ylidene)-1,3-pentadienyl]-1,3,3-trimethyl-3H-indolium iodide
A-4: 2-[7-(1,3-Dihydro-1,3,3-trimethyl-2H-indol-2-ylidene)-1,3,5-heptatrienyl]-1,3,3-trimethyl-3H-indolium iodide
B-1: Polyethylene glycol (average molecular weight 3000)
C-1: bis(3-sulfopropyl)disulfide

### Example 1

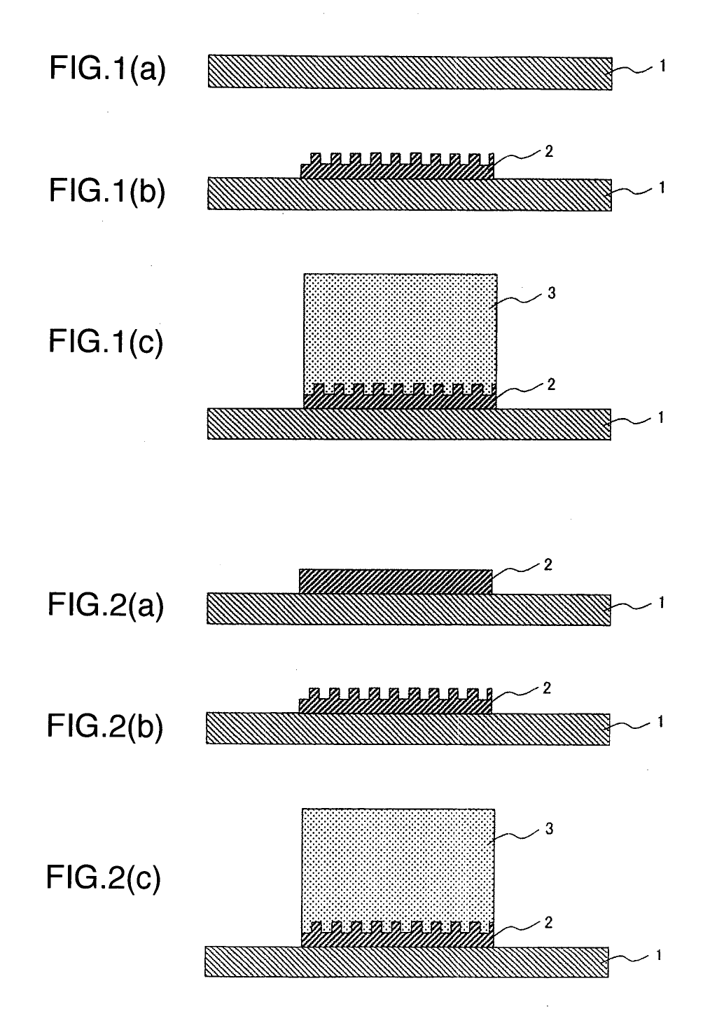

A solution containing dispersed silver particles with an average diameter of 20 nm was sprayed with an ink jet technique onto a surface of an insulating substrate 1 (Kapton EN made by Du Pont-Toray Co., Ltd.) made of polyimide film with a thickness of 25 μm shown in FIG. 1(a) to form a metal seed layer 2 with a wiring width of 20 μm and a thickness of 0.2 μm as shown in FIG. 1(b). Then, the insulating substrate was heated to a temperature of 200° C. to fuse the silver particles. As the insulating substrate, it is possible to use not only the polyimide but also a resin of polyester, class epoxy, phenol, and aramid, ceramics, and glass. As the particles, it is possible to use metal particles of platinum, gold, copper, nickel, tin and the like, other than silver. The roughness on the surface of the metal seed layer formed by the silver particles was measured with a surface roughness measuring apparatus. The measurement showed that the surface roughness of the metal seed layer had an arithmetic average roughness Ra (defined in JIS B0601) of 0.01 μm and an average length of a roughness curve element RSm of 0.02 μm.

Electroplating was performed immediately after the formation of the metal seed layer to form an electroplated copper film 3 as shown in FIG. 1(c). The electroplating was performed by using a plating bath having a composition shown in Table 2 to which a substrate shown in Table 1 is added as an additive. The electroplating was performed for 40 minutes at a current density of 1.25 A/dm² with the plating bath at a temperature of 25° C. Phosphorus copper was used as an anode.

TABLE 2

| Component | Concentration (g/dm³) |
|---|---|
| Copper Sulfate Pentahydrate | 64 |
| Sulfuric Acid | 180 |
| Chloride Ion | 70 × 10⁻³ |

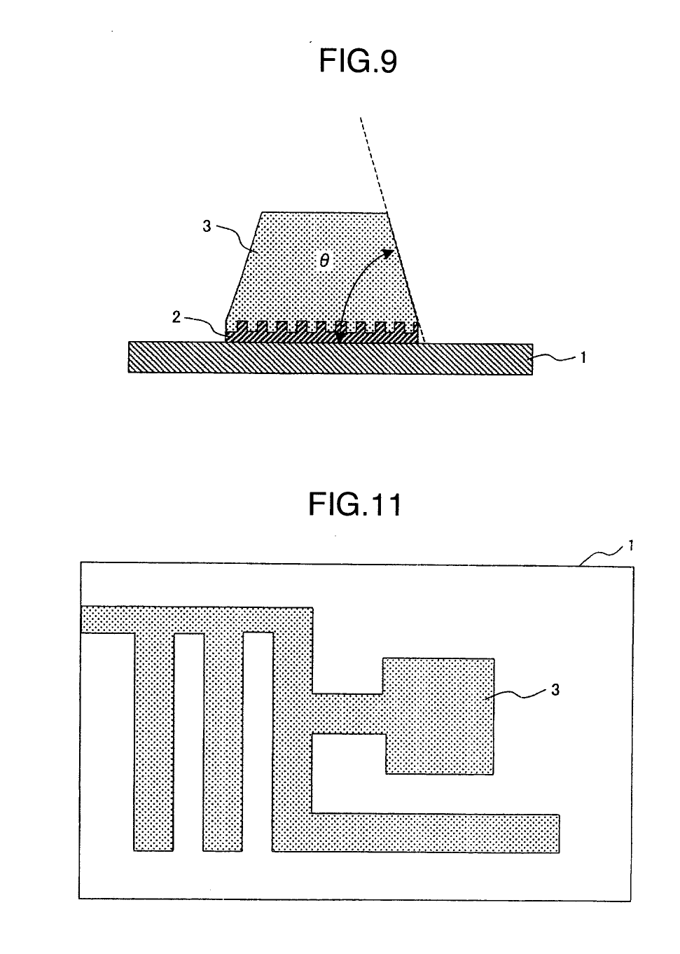

The cross-section of the wiring board was observed after the plating to measure an angle θ between the side wall of the electroplated copper film and the polyimide film substrate as shown in FIG. 9, and an angle of 83 degrees was found.

As a result, it was possible to produce the wiring board in which copper wiring having a generally rectangular wiring section is formed on the metal seed layer including the silver particles. It should be noted that the plan view of the wiring board viewed from the electroplated copper film 3 is as shown in FIG. 11, and this applies to the following Examples.

### Example 2

A metal seed layer 2 with a wiring width of 10 μm was formed as shown in FIG. 2(a) through a mask with a sputtering technique on a surface of an insulating substrate 1 (Upilex S made by Ube Industries Ltd.) made of polyimide film with a thickness of 25 μm shown in FIG. 2(a). The metal seed layer was made of two layers: a nickel film with a thickness of 0.01 μm formed on the substrate and a copper film with a thickness of 0.5 μm formed on the nickel film. As the metal seed layer, it is possible to use not only the stacked film of nickel and copper but also a stacked film of chromium and copper. Then, copper roughening processing was performed to form a roughened shape on the surface of the copper film as shown in FIG. 2(b). The metal seed layer in FIG. 2(b) is made of the two layers, although not shown. The copper roughening processing was performed by using MultiBond made by Nippon MacDermid Co., Inc. in accordance with steps shown in Table 3. As a solution used copper roughening process, it is possible to use MEC etch BOND made by Mec Co., Ltd., Circubond made by Shipley Far East Ltd., Alpha Prep made by Alpha Metals Ltd. and the like, other than the abovementioned one.

TABLE 3

| | | Temperature | Time |
|---|---|---|---|
| Step | Processing Liquid | (° C.) | (Seconds) |
| 1 | 5 vol % Sulfuric Acid | 25 | 30 |
| 2 | Pure Water (Running Water) | 22 | 60 |
| 3 | 2 vol % MB-100B | 25 | 30 |
| | 2.9 vol % MB-100C | | |
| 4 | 5 vol % Sulfuric Acid | 32 | 15 |
| | 15 vol % MB-100A | | |
| | 2 vol % MB-100B | | |
| | 2.9 vol % MB-100C | | |
| 5 | Pure Water (Running Water) | 22 | 60 |

The rough area on the surface of the copper film after the copper roughening processing was measured with a surface roughness measuring apparatus. The measurement showed that the surface roughness of the metal seed layer had an arithmetic average roughness Ra (defined in JIS B0601) of 0.05 μm and an average length of a roughness curve element RSm of 0.04 μm. Electroplating was performed immediately after the formation of the roughened shape on the surface of the copper film in the metal seed layer 2 to form an electroplated copper film 3 as shown in FIG. 2(c). The electroplating was performed by using the same composition of a plating bath and the same plating conditions as those in Example 1. The cross-section of the wiring board was observed after the plating to measure an angle θ between the side wall of the electroplated copper film and the polyimide film substrate as shown in FIG. 9, and an angle of 83 degrees was found.

As a result, it was possible to produce the wiring board in which copper wiring having a generally rectangular wiring section is formed on the copper film formed with the sputtering technique.

### Example 3

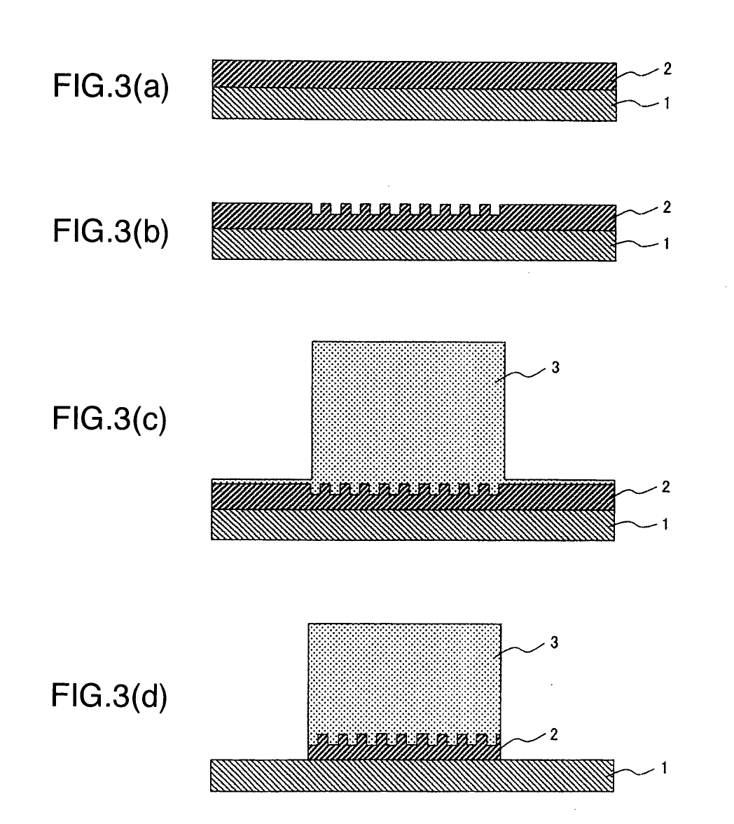

As shown in FIG. 3(a), a nickel film with a thickness of 0.1 μm formed on a surface of an insulating substrate 1 made of glass epoxy resin and a copper film with a thickness of 1.0 μm was formed with the sputtering technique on the nickel film. Next, copper roughening processing was performed to form a rough area in the portion of the copper surface on which wiring was to be formed, thereby providing the shape shown in FIG. 3(b). The rough area was formed with sandblast. The sandblast was performed by spraying alumina particles onto the copper surface through a mask pattern with a wiring width of 8 μm. The roughened shape on the copper surface after the sandblast processing was measured with a surface roughness measuring apparatus. The measurement showed that the surface roughness of the metal seed layer had an arithmetic average roughness Ra (defined in JIS B0601) of 0.4 μm and an average length of a roughness curve element RSm of 1.1 μm. Electroplating was performed immediately after the formation of the roughen area on the copper surface to form an electroplated copper film 3 as shown in FIG. 3(c). The electroplating was performed by using the same composition of a plating bath and the same plating conditions as those in Example 1. Next, a copper etchant (MECBRITE made by Mec Co., Ltd) was used to etch away the portions of the electroplated copper film 3 and the copper seed layer on which the rough area was not formed. In addition, MEC REMOVER made by Mec Co., Ltd was used to remove a portion of the nickel seed layer to provide the structure shown in FIG. 3(d). The cross-section of the wiring board was observed after the plating to measure an angle θ between the side wall of the copper film and the substrate as shown in FIG. 9, and an angle of 85 degrees was found.

As a result, it was possible to produce the wiring board in which copper wiring having a generally rectangular wiring section is formed on the copper seed layer having the roughen area formed thereon through the sandblast.

### Example 4

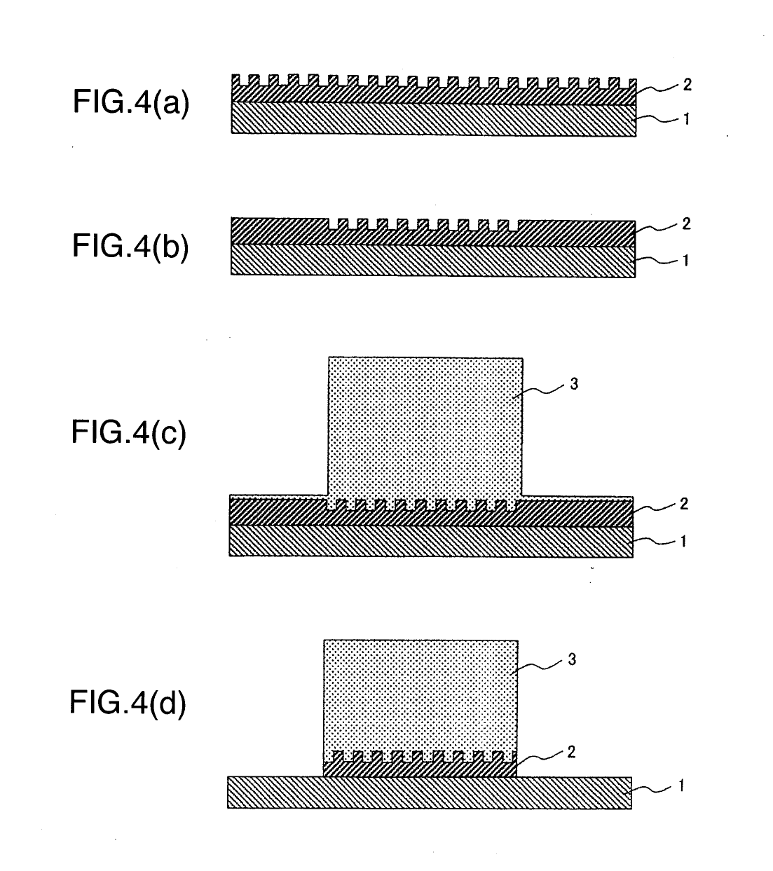

As shown in FIG. 4(a), a surface of an insulating substrate 1 made of polyimide film with a thickness of 25 μm was treated with a surface modification solution shown in Table 4 at a temperature of 25° C. for two minutes and then plating was performed with an electroless copper plating bath (CUST-2000 made by Hitachi Chemical Co., Ltd.) to form a metal seed layer 2. After the plating, the substrate was washed with running water and vacuum drying was performed thereon at 25° C. for two hours. The copper film had a thickness of approximately 300 nm at that point. The roughness on the surface of the copper seed layer after the plating was measured with a surface roughness measuring apparatus. The measurement showed that the surface roughness of the metal seed layer had an arithmetic average roughness Ra (defined in JIS B0601) of 1.5 μm and an average length of a roughness curve element RSm of 1.4 μm.

TABLE 4

| Component | Concentration (g/dm³) |
|---|---|
| Sodium Hydroxide | 100 |
| Ethylenediamine | 70 |
| Ethanol | 100 |

Next, a solution containing dispersed copper particles was sprayed onto the metal seed layer 2 except the portion which would serve as wiring with a width of 10 μm, that is, the portion on which wiring was not to be formed. Then, annealing was performed in vacuum at 350° C. for 30 minutes. The surface roughness of the portion sprayed with the copper particles was measured with a surface roughness measuring apparatus. The measurement showed that the surface roughness had an arithmetic average roughness Ra (defined in JIS B0601) of 0.005 μm and an average length of a roughness curve element RSm of 11 μm, which demonstrated that the surface of the copper film was planarized. FIG. 4(b) shows the structure at that point.

Next, electroplating was performed to form an electroplated copper film 3 as shown in FIG. 4(c). The electroplating was performed by using the same composition of a plating bath and the same conditions as those in Example 1 except the plating time set to 20 minutes. Then, a copper etchant (MECBRITE made by Mec Co., Ltd) was used to etch away the portions of the electroplated copper film and the copper seed layer in which the roughened shape was planarized, thereby providing the structure shown in FIG. 4(d). The cross-section of the wiring board was observed after the plating to measure an angle θ between the side wall of the electroplated copper film and the polyimide film substrate as shown in FIG. 9, and an angle of 80 degrees was found.

As a result, it was possible to produce the wiring board in which copper wiring having a generally rectangular wiring section is formed on the copper seed layer having the rough area formed thereon.

### Example 5

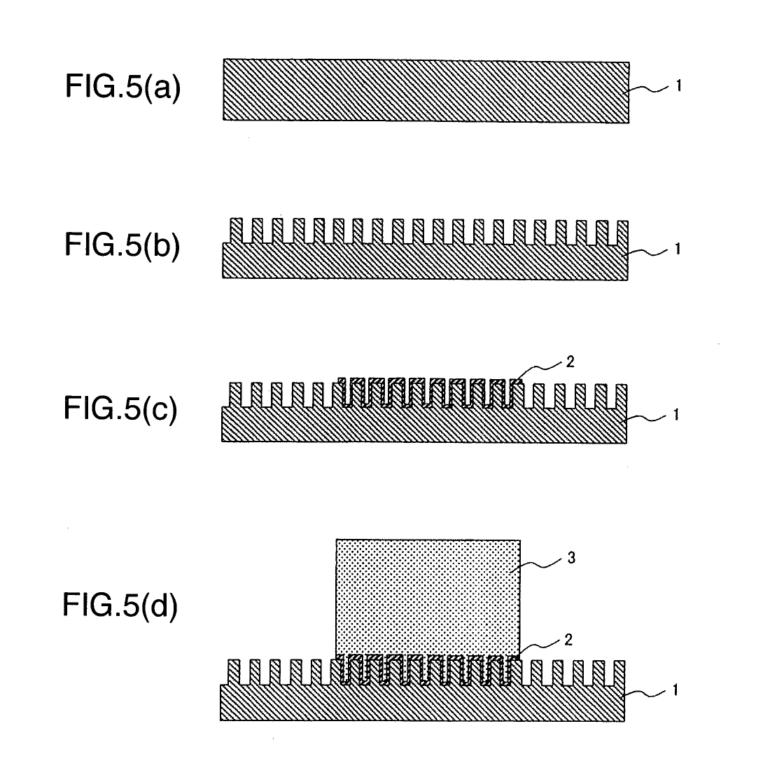

Roughening processing was performed on a surface of an insulating substrate 1 made of polyimide film with a thickness of 25 μm shown in FIG. 5(a) to form a rough area as shown in FIG. 5(b). The roughening processing was performed in accordance with steps shown in Table 5. As a roughening liquid, it is possible to use not only a mixed solution of potassium permanganate solution and sodium hydroxide but also a mixed solution of chromic acid and sulfuric acid, a mixed solution of chromic acid and fluoroboric acid and the like.

TABLE 5

| | | Temperature | Time |
|---|---|---|---|
| Step | Processing Liquid | (° C.) | (Second) |
| 1 | 50 g/dm³ Potassium | 80 | 5 |
| | Permanganate Solution | | |
| | 1 mol/dm³ Sodium Hydroxide | | |
| 2 | 0.5 vol % Sulfuric Acid | 40 | 5 |
| | 0.2 vol % Hydroxylamine | | |
| | Sulfate | | |

Next, a solution containing dispersed copper particles with an average diameter of 10 nm was sprayed onto the surface of the insulating substrate 1 to form a metal seed layer 2 with a wiring width of 30 μm and a thickness of 0.03 μm as shown in FIG. 5(c). The roughness on the surface of the metal seed film formed by the copper particles was measured with a surface roughness measuring apparatus. The measurement showed that the metal seed layer had an arithmetic average roughness Ra (defined in JIS B0601) of 2.0 μm and an average length of a roughness curve element RSm of 4.0 μm.

Electroplating was performed immediately after the formation of the metal seed layer 2 to form an electroplated copper film 3 as shown in FIG. 5(d). The electroplating was performed by using the same composition of a plating bath and the same conditions as those in Example 1. The cross-section of the wiring board was observed after the plating to measure an angle θ between the side wall of the electroplated copper film and the polyimide film substrate as shown in FIG. 9, and an angle of 86 degrees was found.

As a result, it was possible to produce the wiring board in which copper wiring having a generally rectangular wiring section is formed on the metal seed layer formed of the copper particles.

### Example 6

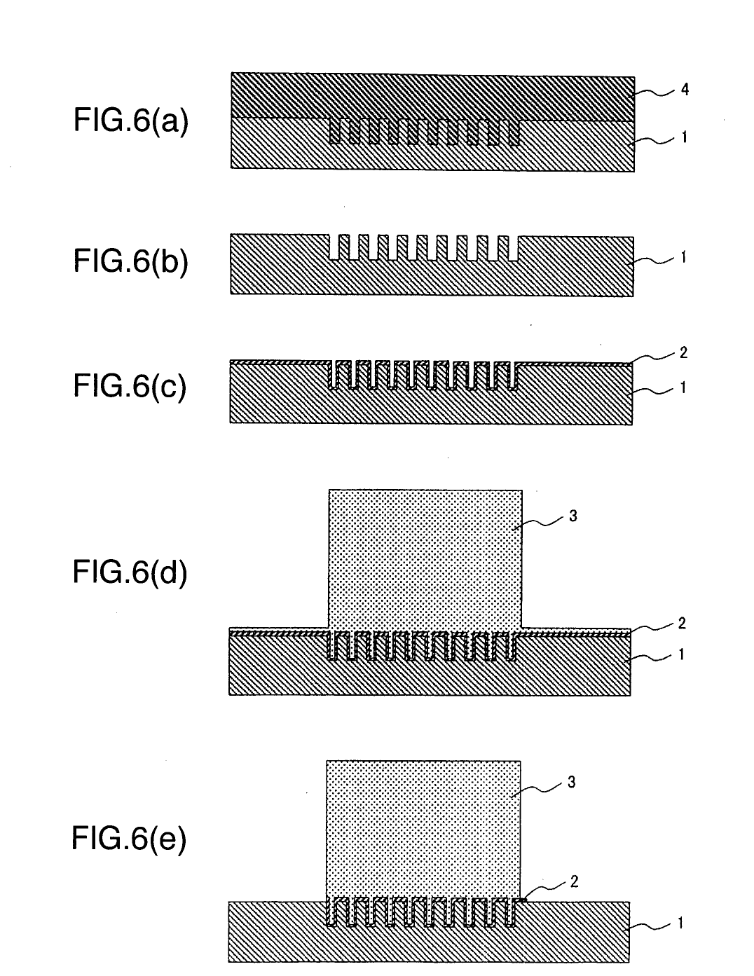

As shown in FIG. 6(a), a mold 4 made of silicon which has a 250 nm pitch protrusion with a width of 250 nm and a height of 400 nm over a width of 10 μm was pushed onto a surface of an insulating substrate 1 made of epoxy resin to form a roughened shape. The mold was pushed onto the insulating substrate 1 while it was heated to near the glass-transition temperature, thereby softening the epoxy resin substrate 1 for deformation to the shape corresponding to the mold. After the insulating substrate 1 and the mold 4 was cooled to 25° C., the mold 4 was separated from the substrate 1. Thus, the rough area was able to be formed on part of the surface of the insulating substrate 1 as shown in FIG. 6(b). Next, a nickel/chromium film made of nickel and chromium at a ratio of 1:1 was formed with a thickness of 10 nm with the sputtering technique on the surface of the insulating substrate 1. A copper film was formed thereon with a thickness of 100 nm through a chemical vapor deposition technique. The nickel/chromium film and the copper film constituted a metal seed layer 2. FIG. 6(c) shows the structure at that point. The observation of the rough area on the surface of the metal seed layer 2 revealed that the metal seed layer 2 maintained the roughened shape of the insulating substrate.

Electroplating was performed immediately after the formation of the metal seed layer 2 to form an electroplated copper film 3 as shown in FIG. 6(d). The electroplating was performed by using the same composition of a plating bath and the same conditions as those in Example 1 except the plating time set to 90 minutes. Next, a solution containing sulfuric acid and hydrogen peroxide was used to remove the portions of the electroplated copper film and the copper film of the metal seed layer on which the rough area was not formed. In addition, a solution containing potassium permanganate solution was used to remove a portion of the nickel/chromium film. The cross-section of the wiring board was observed after the plating to measure an angle θ between the side wall of the electroplated copper film and the substrate as shown in FIG. 9, and an angle of 83 degrees was found.

As a result, it was possible to produce the wiring board in which copper wiring having a generally rectangular wiring section is formed on the copper seed layer having the roughened shape formed thereon.

### Example 7

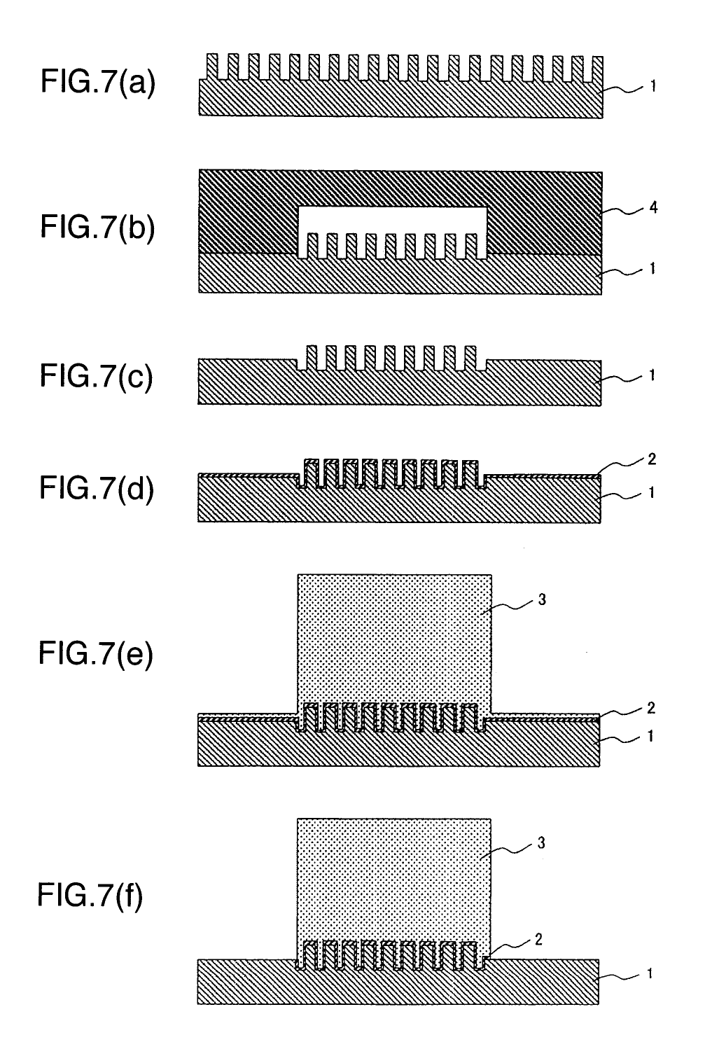

As shown in FIG. 7(a), roughening processing was performed on a surface of an insulating substrate 1 made of polyimide film with a mixed solution of chromic acid and sulfuric acid to form a rough area. The surface roughness of the portion having the rough area was measured with a surface roughness measuring apparatus. The measurement showed that the surface roughness had an arithmetic average roughness Ra (defined in JIS B0601) of 1.0 μm and an average length of a roughness curve element RSm of 1.1 μm. Next, as shown in FIG. 7(b), a mold 4 made of silicon which has a concave portion with a width of 10 μm was pushed onto the surface of the insulating substrate 1 to planarize the roughened shape in the portion on which no wiring was to be formed. The mold was pushed onto the insulating substrate 1 while it was heated to near the glass-transition temperature, thereby softening the insulating substrate for deformation to the shape corresponding to the mold. During the step, the mold 4 was placed such that its concave portion was out of contact with the insulating substrate 1. Then, after the insulating substrate 1 and the mold 4 was cooled to 25° C., the mold 4 was separated from the substrate 1. Thus, the rough area was able to be planarized except part of the surface of the insulating substrate 1 as shown in FIG. 7(c). The surface roughness of the portion where the rough area was planarized was measured with a surface roughness measuring apparatus. The measurement showed that the surface roughness had an arithmetic average roughness Ra (defined in JIS B0601) of 0.006 μm and an average length of a roughness curve element RSm of 9 μm.

Next, a nickel/chromium film made of nickel and chromium at a ratio of 1:1 was formed with a thickness of 10 nm through the sputtering technique on the surface of the insulating substrate 1. A copper film was formed thereon with a thickness of 100 nm through the chemical vapor deposition technique. The nickel/chromium film and the copper film constituted a metal seed layer 2. FIG. 7(d) shows the structure at that point. The surface roughness of the portion of the metal seed layer 2 on which the roughened shape was formed was measured with a surface roughness measuring apparatus. The measurement showed that the surface roughness had an arithmetic average roughness Ra (defined in JIS B0601) of 1.0 μm and an average length of a roughness curve element RSm of 1.1 μm. The measurement demonstrated that the metal seed layer 2 maintained the roughened shape of the insulating substrate.

Electroplating was performed immediately after the formation of the metal seed layer 2 to form an electroplated copper film 3 as shown in FIG. 7(e). The electroplating was performed by using the same composition of a plating bath and the same conditions as those in Example 1. Next, a solution containing sulfuric acid and hydrogen peroxide was used to remove the portions of the electroplated copper film 3 and the copper of the metal seed layer on which the rough area was not formed. Subsequently, a solution containing potassium permanganate solution was used to remove a portion of nickel/chromium film. The cross-section of the wiring board was observed after the plating to measure an angle θ between the side wall of the electroplated copper film and the polyimide film substrate as shown in FIG. 9, and an angle of 89 degrees was found.

As a result, it was possible to produce the wiring board in which copper wiring having a generally rectangular wiring section is formed on the metal seed layer having the roughened shape formed thereon.

### Example 8

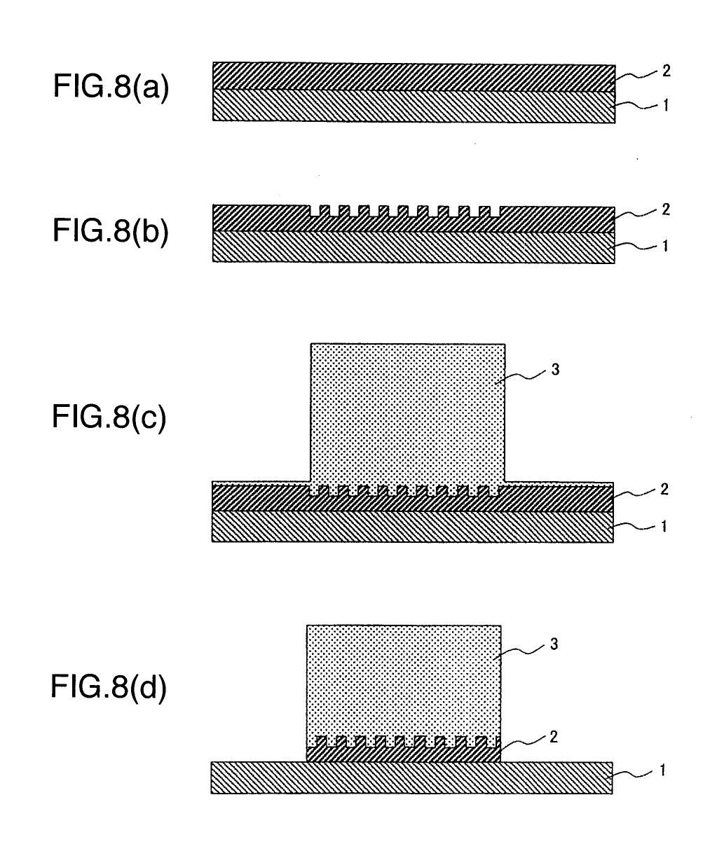

As shown in FIG. 8(a), an insulating substrate 1 made of polyimide with a thickness of 25 μm was formed with a casting method on a mat surface of a metal seed layer 2 made of electrolytic copper foil with a thickness of 8 μm. Next, copper roughening processing was performed to form a rough area in a portion of a surface of the metal seed layer on which wiring was to be formed as shown in FIG. 8(b). The roughened shape was formed with sandblast. The sandblast was performed by spraying alumina particles onto the surface of the metal seed layer through a mask pattern with a wiring width of 10 μm. The roughened shape on the surface of the metal seed layer after the sandblast processing was measured with a surface roughness measuring apparatus. The measurement showed that the surface roughness had an arithmetic average roughness Ra (defined in JIS B0601) of 0.4 μm and an average length of a roughness curve element RSm of 1.1 μm. Electroplating was performed immediately after the formation of the roughened shape on the copper surface to form an electroplated copper film 3 as shown in FIG. 8(c). The electroplating was performed by using the same composition of a plating bath and the same plating conditions as those in Example 1. Next, a copper etchant (MECBRITE made by Mec Co., Ltd) was used to etch away the portions of the electroplated copper film 3 and the copper foil on which the rough area was not formed, thereby providing the structure shown in FIG. 8(d). The cross-section of the wiring board was observed after the plating to measure an angle θ between the side wall of the electroplated copper film and the polyimide film substrate as shown in FIG. 9, and an angle of 85 degrees was found.

As a result, it was possible to produce the wiring board in which copper wiring having a generally rectangular wiring section is formed on the metal seed layer having the roughened shape formed thereon with the sandblast.

### Example 9 to 22

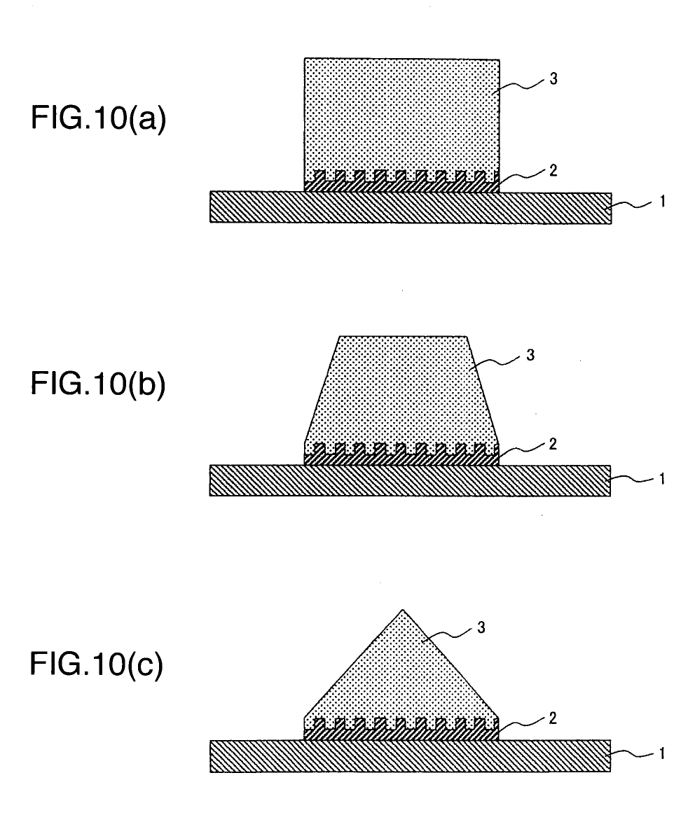

As shown in Table 1, wiring boards of Examples 9 to 22 were produced in the same manner as in Example 3 except the additive concentration and plating current density. The observation of the cross-sections of the wiring boards after plating showed that the angle θ between the side wall of the electroplated copper film and the substrate as shown in FIG. 9 depended on the additive concentration and plating current density, and therefore the angle θ can be controlled by changing those conditions. As a result, wiring boards were able to be produced to have wiring or bumps with a rectangular, trapezoidal, or triangular section as shown in FIG. 10(a), 10(b), or 10(c). In addition, in Examples 9 to 22, the ratio of the height of the side wall of the wiring to the width of the bottom of the wiring can be set to one or higher and the wiring boards can be produced with high electromigration resistance.

### Comparative Example 1

Wiring was formed by performing electroplating in the same manner as in Example 2 except that no roughening processing was performed. The cross-section of the wiring board was observed after the plating to measure an angle θ between the side wall of an electroplated copper film and a substrate as shown in FIG. 9, and an angle of 135 degrees was found. The wiring with a width of 10 μm before the electroplating had a wiring width of 18 μm after the electroplating, and short-circuit was found.

Since plating can be performed on a fine pattern without masking by a resist, the present invention is applicable not only to the formation of wiring or bumps but also to the formation of a device mounted on a wiring board such as a passive device.

It should be further understood by those skilled in the art that although the foregoing description has been made on embodiments of the invention, the invention is not limited thereto and various changes and modifications may be made without departing from the spirit of the invention and the scope of the appended claims.

1. A method of producing a wiring board having copper wiring on an insulating substrate, comprising the steps of:
forming a metal seed layer on the insulating substrate, the metal seed layer having a roughened shape in a portion on which the copper wiring is to be formed; and
forming an electroplated copper film on the portion of the metal seed layer having the roughened shape through electroplating using a plating bath containing a substance for suppressing plating reaction,
wherein the electroplated copper film is formed at an angle of 90 degrees or smaller between a surface of the insulating substrate and a side of the electroplated copper film.

2. The method of producing a wiring board according to claim 1, wherein the angle between the surface of the insulating substrate and the side of the electroplated copper film is adjusted by controlling a current density in performing the electroplating.

3. The method of producing a wiring board according to claim 1, wherein the metal seed layer is formed on the insulating substrate and then the roughened shape is formed thereon, and the electroplated copper film is formed on the metal seed layer through the electroplating and then the metal seed layer and the electroplated copper film are removed except their portions having the roughened shape thereon.

4. The method of producing a wiring board according to claim 1, wherein the metal seed layer having the roughened shape formed thereon is formed on the insulating substrate, the roughened shape is planarized except its portion on which the copper wiring or bumps are to be formed, the electroplated copper film is formed through the electroplating on the metal seed layer, and then the metal seed layer and the electroplated copper film are removed except their portions having the roughened shape thereon.

5. The method of producing a wiring board according to claim 1, wherein the metal seed layer serving as a power supply layer for the electroplating is formed, and then an insulating film serving as the insulating substrate is formed on the metal seed layer with a casting method, the roughened shape is formed in a portion of the metal seed layer on which wiring or bumps are to be formed, the electroplated copper film is formed on the metal seed layer through the electroplating, and the metal seed layer and the electroplated copper film are removed except their portions having the roughened shape thereon.

6. The method of producing a wiring board according to claim 1, wherein an arithmetic average roughness Ra, defined in JIS B0601, of the portion having the roughened shape of the insulating substrate or the metal seed layer is larger than an arithmetic average roughness Ra of the remaining portion.

7. The method of producing a wiring board according to claim 1, wherein an average length of a roughness curve element RSm, defined in JIS B0601, of the portion having the roughened shape of the insulating substrate or the metal seed layer is smaller than an average length RSm of the remaining portion.

8. The method of producing a wiring board according to claim 1, wherein the surface roughness of the portion having the roughened shape has an arithmetic average roughness Ra, defined in JIS B0601, of 0.01 to 4 μm, and an average length of a roughness curve element RSm of 0.005 to 8 μm.

9. The method of producing a wiring board according to claim 1, wherein the substance added to the plating bath increases the overpotential of the metal deposition through the electroplating when the velocity of the plating bath containing the substrate to increases.

10. The method of producing a wiring board according to claim 1, wherein at least one of cyanine dyes is added to the plating bath.

11. The method of producing a wiring board according to claim 10, wherein the cyanine dye is a compound shown in the following formula (where X represents an anion and n represents one of the numbers 0, 1, 2, and 3):

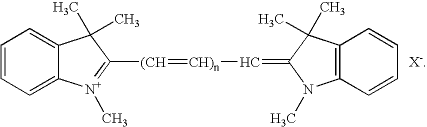

12. The method of producing a wiring board according to claim 10, wherein the cyanine dye has a concentration of 3 to 15 mg/dm³.

13. The method of producing a wiring board according to claim 10, wherein the electroplating is performed with a constant current at a current density of 0.1 to 2.0 A/dm².

14. The method of producing a wiring board according to claim 1, wherein at least one substance selected from a polyether, an organic sulfur compound, and a halide ion is added to the plating bath.

15. A wiring board comprising:
an insulating substrate;
a metal seed layer on said insulating substrate; and
an electroplated copper film on said metal seed layer,
said metal seed layer having a roughened shape on its surface, further comprising wiring or bumps formed through electroplating on the portion of said metal seed layer having the roughened shape, and an angle between a surface of said insulating substance and a side of the wiring or bump being 90 degrees or smaller.

16. The wiring board according to claim 15, wherein an arithmetic average roughness Ra, defined in JIS B0601, of the portion having the roughened shape of said insulating substrate or said metal seed layer is larger than an arithmetic average roughness Ra of the remaining portion.

17. The wiring board according to claim 15, wherein an average length of a roughness curve element RSm, defined in JIS B0601, of the portion having the roughened shape of said insulating substrate or said metal seed layer is smaller than an average length RSm of the remaining portion.

18. The wiring board according to claim 16, wherein the surface roughness of the portion having the roughened shape of said metal seed layer on which said electroplated copper film is formed has an arithmetic average roughness Ra, defined in JIS B0601, of 0.01 to 4 μm.

19. The wiring board according to claim 17, wherein the surface roughness of the portion having the roughened shape of said metal seed layer on which said electroplated copper film is formed has an average length of a roughness curve element RSm, defined in JIS B0601, of 0.005 to 8 μm.

20. The wiring board according to claim 15, wherein said electroplated copper film has a surface in parallel with the surface of said insulating substrate.
